(19) United States
(12) Patent Application Publication
(10) Pub. No.: US 2009/0124225 A1
(43) Pub. Date: May 14, 2009

(54) TUNING CIRCUIT AND RADIO RECEIVER USING THE SAME

(76) Inventors: Kazuhisa Ishiguro, Ota-shi (JP); Yoshiaki Takahashi, Ora-gun (JP)

Correspondence Address: SMITH PATENT OFFICE, 1901 PENNSYLVANIA AVENUE N W, SUITE 901, WASHINGTON, DC, 20006, US

(21) Appl. No.: 12/267,272

(22) Filed: Nov. 7, 2008

(30) Foreign Application Priority Data
Nov. 9, 2007 (JP) 2007-292500

(51) Int. Cl. H04B 1/16; H03H 7/01

(52) U.S. Cl. 455/150.1; 333/175

(57) ABSTRACT

In a tuning circuit constituted by connecting a coil L and two capacitors C1 and C2 into a π type, a total capacitance value obtained by adding respective capacitance values of an input capacitance Cin and the first capacitor C1 which are connected to one of terminals of a coil L is set to be equal to a capacitance value of the second capacitor C2 connected to the other terminal of the coil L (C2=Cin+C1). Consequently, a capacitance value on one terminal side of the coil L and a capacitance value on the other terminal side are set to be equal to each other and are thus balanced, and a level difference between two output signals on a parallel resonance point of the π type tuning circuit is reduced even if the capacitance values of the two capacitors C1 and C2 are decreased.

### FIELD OF THE INVENTION

The present invention relates to a tuning circuit and a radio receiver using the tuning circuit, and more particularly to a π type tuning circuit constituted by connecting a capacitor and a coil into a π type.

### DESCRIPTION OF THE RELATED ART

In a wireless receiving apparatus such as a radio receiver, it is necessary to remove an unnecessary frequency component by using a filter in order to receive only a signal in a target frequency region well and to prevent a disturbance from being received from a signal other than a target frequency band. For the simplest receiving band selecting filter, a tuning circuit (an LC resonance circuit) is used in some cases. The tuning circuit includes a π type tuning circuit constituted by connecting a capacitor and a coil into a π type (for example, see Patent Document 1).
[Patent Document 1] Japanese Laid-Open Patent Publication No. 9-46182

FIG. 6 is a diagram showing an example of a structure of a conventional π type tuning circuit. The π type tuning circuit shown in FIG. 6 is a single tuning circuit including only one resonance circuit. As shown in FIG. 6, in the π type tuning circuit, one of terminals of a coil L is earthed into a ground terminal GND through a capacitor C1 and the other terminal is grounded through a capacitor C2. In general, two capacitors C1 and C2 to be used have equal capacitance values. Moreover, one of the terminals of the coil L is connected to an output terminal OUT1 and the other terminal is connected to an output terminal OUT2. An input capacitance Cin and a signal source resistor Rs are connected in series between an input terminal IN and one of the terminals of the coil L.

Signals sent from the two output terminals OUT1 and OUT2 of the π type tuning circuit are input to a differential amplifier of a mixer (a frequency converting circuit) corresponding to a subsequent stage to a radio receiver, for example. The differential amplifier has a property referred to as a common mode rejection which does not have a gain when signals (referred to as common mode signals) each having an identical amplitude (level) are input from two input terminals.

In order to obtain the common mode rejection characteristic at a maximum, it is necessary to set the signals sent from the two output terminals OUT1 and OUT2 of the π type tuning circuit to have an identical level. If the identical amplitude is not set, the common mode rejection characteristic cannot be obtained and a level difference between two output signals in the π type tuning circuit serves as a differential input in the differential amplifier. The level difference is amplified to influence a noise characteristic.

In order to set the signals sent from the two output terminals OUT1 and OUT2 of the π type tuning circuit to have the identical level, conventionally, two capacitors C1 and C2 to be used have sufficiently greater capacitance value than the input capacitance Cin. By using the capacitors C1 and C2 having the great capacitance values, thus, it is possible to substantially disregard the capacitance value of the input capacitance Cin.

### DISCLOSURE OF THE INVENTION

However, there is a problem in that it is hard to provide the capacitors C1 and C2 in an IC chip if their capacitance values are increased. If the capacitance values of the capacitors C1 and C2 are reduced in such a manner that they can be provided in the IC chip, a level difference between the signals sent from the two output terminals OUT1 and OUT2 of the π type tuning circuit is increased. For example, if the capacitance values of the capacitors C1 and C2 are set to be C1=C2=8 pF when the capacitance value of the input capacitance Cin is 7 pF, for example, a level difference between two output signals on a parallel resonance point of the π type tuning circuit is as much as 5 dB as shown in FIG. 7.

In order to solve the problem, it is an object of the present invention to provide a π type tuning circuit in which a capacitance value of a capacitor can be decreased and the capacitor can be thus provided in an IC chip, and a level difference between output signals can be reduced.

In order to attain the object, in the present invention, a total capacitance value obtained by adding capacitance values of an input capacitance and a first capacitor which are connected to one of terminals of a coil is set to be equal to a capacitance value of a second capacitor which is connected to the other terminal of the coil in a tuning circuit constituted by connecting the coil and the two capacitors into a π type.

According to the present invention having the structure described above, the capacitance value on one terminal side of the coil and the capacitance value on the other terminal side are equal to each other and are thus balanced including the capacitance value of the input capacitance connected to the one terminal side. Even if the capacitance values of two capacitors are reduced, therefore, it is possible to decrease a level difference between two output signals on a parallel resonance point of the π type tuning circuit. Consequently, it is possible to bring out the common mode rejection characteristic of a differential amplifier connected to a subsequent stage to the tuning circuit at a maximum, thereby obtaining an excellent noise characteristic. Moreover, since the capacitance value of the capacitor is small, the capacitor can also be provided in an IC chip.

### BRIEF DESCRIPTION OF THE DRAWINGS

FIG. 1 is a diagram showing an example of a structure of a π type tuning circuit carrying out a tuning circuit according to the present invention,

FIG. 2 is a chart showing a resonance characteristic of the π type tuning circuit according to the present embodiment,

FIG. 3 is a chart showing the resonance characteristic of the π type tuning circuit according to the present embodiment,

FIG. 4 is a chart showing a resonance characteristic of a conventional π type tuning circuit,

FIG. 5 is a diagram showing an example of a structure of a part of a radio receiver applying the π type tuning circuit according to the present embodiment,

FIG. 6 is a diagram showing an example of a structure of a conventional π type tuning circuit, and

FIG. 7 is a chart showing a resonance characteristic of the conventional π type tuning circuit.

### BEST MODE FOR CARRYING OUT THE INVENTION

An embodiment according to the present invention will be described below with reference to the drawings. FIG. 1 is a diagram showing an example of a structure of a π type tuning circuit carrying out a tuning circuit according to the present invention. As shown in FIG. 1, the π type tuning circuit according to the present embodiment includes a coil L having one of terminals connected to an output terminal OUT1 and the other terminal connected to an output terminal OUT2, a first capacitor C1 connected between one of the terminals of the coil L and a ground terminal GND, and a second capacitor C2 connected between the other terminal of the coil L and the ground terminal GND.

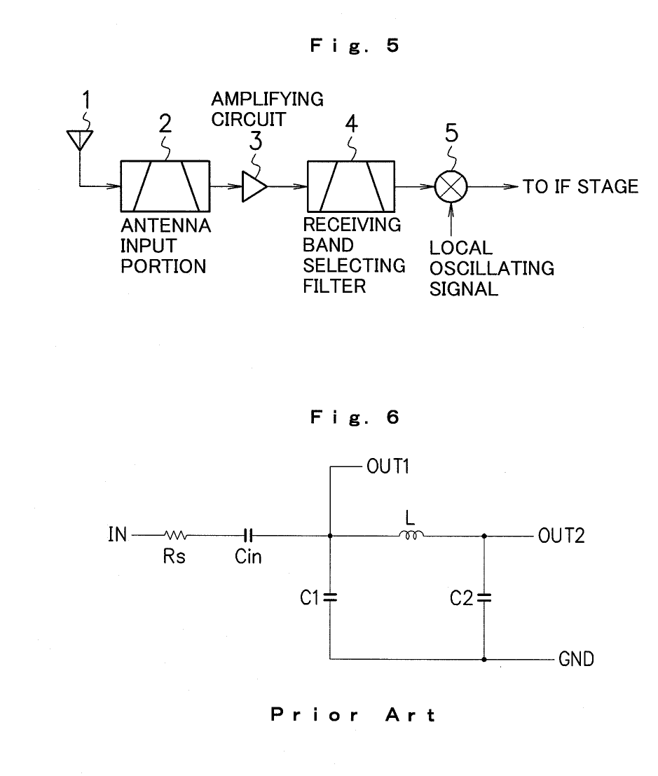

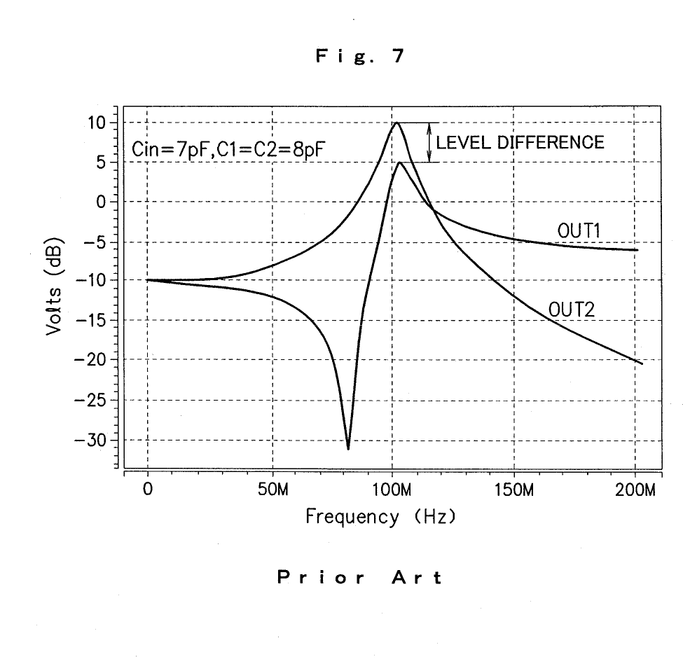

More specifically, in the same manner as in the conventional example shown in FIG. 6, one of the terminals of the coil L is earthed into the ground terminal GND through the first capacitor C1 and the other terminal is grounded through the second capacitor C2. Moreover, one of the terminals of the coil L is connected to the output terminal OUT1 and the other terminal is connected to the output terminal OUT2. An input capacitance Cin and a single source resistor Rs are connected in series between an input terminal IN and one of the terminals of the coil L.

In the present embodiment, a total capacitance value obtained by adding a capacitance value of the input capacitance Cin and that of the first capacitor C1 is set to be almost equal to a capacitance value of the second capacitor C2 (Cin+C1≈C2). It is preferable that the total capacitance value obtained by adding the capacitance value of the input capacitance Cin and that of the first capacitor C1 should be set to be perfectly equal to the capacitance value of the second capacitor C2 (Cin+C1=C2).

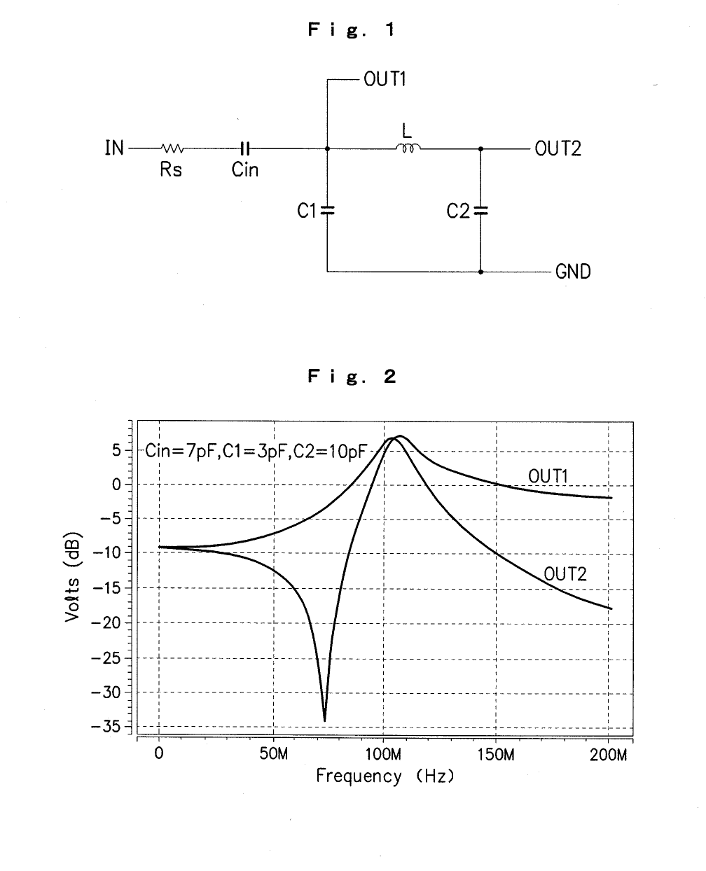

For example, in the case in which the π type tuning circuit is to be resonated at approximately 104 MHz, it is assumed that the capacitance value of the first capacitor C1 is set to be 3 pF when the capacitance value of the input capacitance Cin is 7 pF. In this case, the capacitance value of the second capacitor C2 is set to be C2=7+3=10 pF. Thus, the capacitance value on one terminal side of the coil L and the capacitance value on the other terminal side are equal to each other and are thus balanced including the capacitance value of the input capacitance Cin connected to the one terminal side of the coil L. As shown in FIG. 2, therefore, a level difference between two output signals on a parallel resonance point of the π type tuning circuit is almost eliminated.

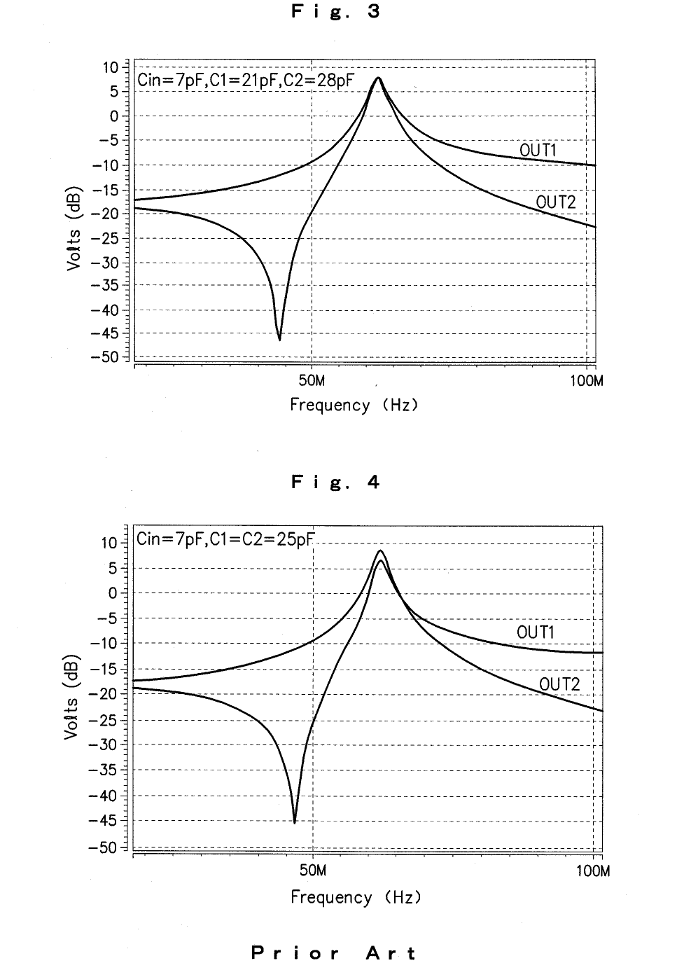

In the case in which the π type tuning circuit is to be resonated at approximately 62 MHz, moreover, it is assumed that the capacitance value of the first capacitor C1 is set to be 21 pF when the capacitance value of the input capacitance Cin is 7 pF. In this case, the capacitance value of the second capacitor C2 is set to be C2=7+21=28 pF. As shown in FIG. 3, thus, the level difference between the two output signals on the parallel resonance point of the π type tuning circuit is almost eliminated. Also in the case in which the π type tuning circuit is to be resonated at another frequency, similarly, it is possible to reduce the level difference between the two output signals in the π type tuning circuit so as to be disregarded by setting Cin+C1=C2.

FIG. 4 shows a characteristic in the case in which C1=C2 (C1=C2=25 pF in an example of FIG. 4) is conventionally set when the π type tuning circuit is to be resonated at approximately 62 MHz. As is apparent from a comparison with FIG. 7, a level difference between output signals is reduced when a resonance frequency is decreased. However, the level difference has a great value which cannot be disregarded, that is, 1 dB or more. On the other hand, according to the present embodiment, it is possible to reduce the level difference between two output signals in the π type tuning circuit so as to be disregarded also when the π type tuning circuit is to be resonated at any frequency.

FIG. 5 is a diagram showing an example of a structure of a part (a front end portion) of a radio receiver applying the π type tuning circuit according to the present embodiment which has the structure described above. In FIG. 5, an antenna input portion 2 inputs a radio frequency signal received by an antenna 1 to a radio frequency amplifying circuit 3. The antenna input portion 2 includes a matching circuit for taking impedance matching with the antenna 1.

Moreover, the antenna input portion 2 also includes a filter circuit for eliminating a disturbance signal other than a target receiving frequency band (which is referred to as an “input side filter” for the radio frequency amplifying circuit 3). The input side filter eliminates a signal of an unnecessary frequency band causing a receiving disturbance in order to avoid a spurious receipt or an intermodulation which is represented by an image disturbance. In order to reduce a loss and to decrease a noise factor as greatly as possible, a frequency selectivity of a comparatively broad band is used.

The radio frequency amplifying circuit 3 amplifies the radio frequency signal input from the antenna input portion 2 and supplies a result to a receiving band selecting filter 4. In the receiving band selecting filter 4 (which is referred to as an “output side filter” for the radio frequency amplifying circuit 3), a pass band is set to be narrow in order to enhance a disturbance eliminating capability as compared with the input side filter of the antenna input portion 2. For this reason, a loss is increased. In order to reduce the noise factor, therefore, the radio frequency amplifying circuit 3 is provided in a former stage of the receiving band selecting filter 4 to amplify the radio frequency signal up to a necessary level for ensuring a predetermined sensitivity performance.

The receiving band selecting filter 4 removes an unnecessary frequency component in order to receive only a signal in a target frequency band well and to prevent a disturbance from being received from a signal in a frequency band other than the target frequency band. For the receiving band selecting filter 4, the π type tuning circuit according to the present embodiment is used. For example, in the case in which a target receiving frequency band is broad as in an FM broadcast, it is ideal to employ a method of setting a tuning frequency to be variable corresponding to a target frequency by using a π type tuning circuit having a high frequency selectivity (a narrow pass band and high Q).

A mixer 5 uses a signal having a local oscillating frequency which is given from an oscillating circuit which is not shown to convert a radio frequency signal having a target receiving frequency passing through the receiving band selecting filter 4 into an intermediate frequency signal (an IF signal). A structure of an IF stage (not shown) is connected to a subsequent stage to the mixer 5.

Although the description has been given to the example in which the π type tuning circuit according to the present embodiment is used in the receiving band selecting filter 4 (the output side filter), it may be used in the antenna input portion 2 (the input side filter).

As described above in detail, according to the present embodiment, even if the capacitance values of the two capacitors C1 and C2 are decreased, the level difference between the two output signals on the parallel resonance point of the π type tuning circuit can be decreased to have a very small value, that is, 1 dB or less. Consequently, the two capacitors C1 and C2 can be provided in an IC chip such as a CMPS (Complementary Metal Oxide Semiconductor) and a common mode rejection characteristic of a differential amplifier to be connected to a subsequent stage to the π type tuning circuit can be brought out at a maximum. Thus, a noise characteristic can be enhanced.

The embodiment is only illustrative for a materialization to carry out the present invention and the technical range of the present invention should not be thereby construed to be restrictive. More specifically, the present invention can be carried out in various forms without departing from the spirit or main features thereof.

### INDUSTRIAL APPLICABILITY

The π type tuning circuit according to the present invention can be utilized as a filter for receiving only a signal in a target frequency band well to remove an unnecessary frequency component in a wireless receiving apparatus such as a radio receiver.

What is claimed is:

1. A tuning circuit comprising:
a coil having one of terminals connected to one of output terminals and the other terminal connected to the other output terminal;
a first capacitor connected between the one of the terminals of the coil and a ground terminal; and
a second capacitor connected between the other terminal of the coil and the ground terminal,
wherein a total capacitance value obtained by adding a capacitance value of an input capacitance connected between the one of the terminals of the coil and an input terminal and a capacitance value of the first capacitor is set to be equal to a capacitance value of the second capacitor.

2. A radio receiver comprising:
the tuning circuit according to claim 1 which outputs a radio frequency signal tuned to a target frequency band; and
a frequency converting circuit for converting the radio frequency signal passing through the tuning circuit into an intermediate frequency signal.

3. A radio receiver comprising:
the tuning circuit according to claim 1 which outputs a radio frequency signal tuned to a target frequency band; and
a radio frequency amplifying circuit for amplifying the radio frequency signal passing through the tuning circuit.
